(19) United States
(12) Patent Application Publication
(10) Pub. No.: US 2016/0141323 A1
(43) Pub. Date: May 19, 2016

(54) SOLID-STATE IMAGING APPARATUS

(71) Applicant: CANON KABUSHIKI KAISHA, Tokyo (JP)

(72) Inventors: Kazuya Igarashi, Tokyo (JP); Zempei Wada, Tokyo (JP)

(21) Appl. No.: 14/919,795

(22) Filed: Oct. 22, 2015

(30) Foreign Application Priority Data
Nov. 14, 2014 (JP) 2014-231765

(51) Int. Cl. H01L 27/146

(52) U.S. Cl. CPC H01L 27/14627; H01L 27/1462; H01L 27/14621

(57) ABSTRACT

A solid-state imaging apparatus having a sensitivity difference between microlens regions hardly be recognized comprises: a plurality of pixels each of which has a photoelectric conversion portion, an optical element arranged above the photoelectric conversion portion, and a microlens arranged above the optical element, wherein the microlenses of the plurality of pixels include a plurality of microlenses of a first microlens structure arranged in a first microlens region, and a plurality of microlenses of a second microlens structure arranged in a second microlens region, the optical elements of the plurality of pixels include a plurality of optical elements of a first optical element structure arranged in a first optical element region, and a plurality of optical elements of a second optical element structure arranged in a second optical element region, and the first microlens region is arranged above a boundary between the first and second optical element regions.

### BACKGROUND OF THE INVENTION

1. Field of the Invention

The present invention relates to a solid-state imaging apparatus.

2. Description of the Related Art

It is demanded for a solid-state imaging apparatus to be mounted on a personal digital assistant and a mobile device, from a market, and the size and the thickness of the solid-state imaging apparatus are progressively reduced. Along with the tendency of reduction in the size and the thickness of the solid-state imaging apparatus, a distance between an imaging lens and the solid-state imaging apparatus is reduced, but when the distance between the imaging lens and the solid-state imaging apparatus decreases, a light incident angle increases in a peripheral region in an imaging region. As a result, in the peripheral region in the imaging region of the solid-state imaging apparatus, such a phenomenon of so-called shading results in occurring that the sensitivity to detect light lowers.

With respect to this problem, such a method is proposed as to form a microlens into a shape suitable for a large light incident angle. A method in Japanese Patent Application Laid-Open No. 2009-94339 includes: dividing the imaging region into a plurality of compartments; designing microlenses so as to have suitable shapes for the large light incident angle in the respective compartments; arranging the microlenses in the respective compartments; and thereby simplifying the design operation. The solid-state imaging apparatus described in Japanese Patent Application Laid-Open No. 2009-94339 has the imaging region which is divided into a plurality of compartments between the central part and the peripheral region, and has microlenses with different shapes formed in the respective compartments. The solid-state imaging apparatus, at this time, also makes a part of the microlenses of the adjacent compartments in the boundary portion between the compartments arranged in the own compartment, and thereby is intended to alleviate the discontinuity in sensitivity change, which occurs in the boundary portion.

However, the above described method of making a part of the microlenses of the adjacent compartments in the boundary portion between the compartments arranged in the own compartment microscopically improves a sensitivity difference, but has the following problem. Specifically, when the difference in sensitivity has occurred between the units of the compartment, even though the sensitivity difference in the boundary portion has been eliminated, which is disclosed in Japanese Patent Application Laid-Open No. 2009-94339, the difference is still visually recognized as an image having a discontinuous portion of brightness, which originates in the sensitivity difference between the units of the compartment.

### SUMMARY OF THE INVENTION

An object of the present invention is to provide a solid-state imaging apparatus in which a sensitivity difference between microlens regions that have different microlens structures is hard to be visually recognized.

According to an aspect of the present invention, a solid-state imaging apparatus comprises: a plurality of pixels arranged two-dimensionally, wherein each of the plurality of pixels has a photoelectric conversion portion, an optical element arranged above the photoelectric conversion portion, and a microlens arranged above the optical element, wherein the microlenses of the plurality of pixels include a plurality of microlenses of a first microlens structure arranged in a first microlens region, and a plurality of microlenses of a second microlens structure different from the first microlens structure arranged in a second microlens region, the optical elements of the plurality of pixels include a plurality of optical elements of a first optical element structure arranged in a first optical element region, and a plurality of microlenses of a second optical element structure arranged in a second optical element region, and the first microlens region is arranged above a boundary between the first and second optical element regions.

Further features of the present invention will become apparent from the following description of exemplary embodiments with reference to the attached drawings.

### BRIEF DESCRIPTION OF THE DRAWINGS

FIG. 1 is a schematic cross-sectional view for describing a first embodiment.

FIGS. 2A, 2B and 2C are schematic plan views for describing the first embodiment.

FIG. 3 is a cross-sectional view of a microlens arranged in an imaging region.

FIG. 4 is a cross-sectional view of a microlens arranged in the imaging region.

FIG. 5 is a schematic plan view of a top wiring layer.

FIG. 6 is a view illustrating a relationship between an opening size of the top wiring layer and the sensitivity.

FIGS. 7A, 7B, 7C and 7D are views in which the top wiring layer having different opening sizes therein is arranged in each of the partial regions.

FIGS. 8A and 8B are views illustrating a boundary portion between adjacent regions.

FIG. 9 is a view illustrating transmissivity of an anti-reflection film.

FIG. 10 is a view illustrating a relationship between a film thickness of a color filter and the sensitivity.

FIGS. 11A, 11B, 11C and 11D are schematic plan views for describing a fourth embodiment.

FIGS. 12A, 12B and 12C are schematic plan views for describing a fifth embodiment.

FIG. 13 is a schematic plan view for describing a sixth embodiment.

### DESCRIPTION OF THE EMBODIMENTS

Preferred embodiments of the present invention will now be described in detail in accordance with the accompanying drawings.

The present invention will be described below with reference to a plurality of embodiments. Each of the embodiments is a part of the present invention and can be appropriately changed. Accordingly, the present invention is not limited to the embodiments. It is also possible to combine one of the plurality of embodiments with the others.

### First Embodiment

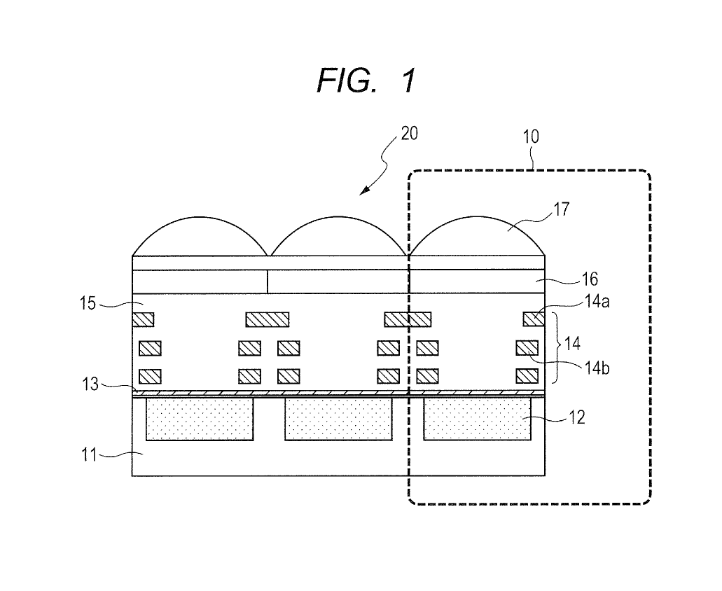

FIG. 1 is a cross-sectional view illustrating a configuration example of a solid-state imaging apparatus 20 according to a first embodiment of the present invention. The solid-state imaging apparatus 20 has a plurality of pixels 10 which are arrayed two-dimensionally. In each of the plurality of pixels 10, a photoelectric conversion portion 12 which is formed on a surface layer portion of a semiconductor substrate 11, an anti-reflection film 13, a multilayer wiring layer 14, a color filter 16 and a microlens 17 are provided in this order. The photoelectric conversion portion 12 is, for instance, a photo diode, and converts light which has been condensed by the microlens 17 into an electron. The anti-reflection film 13 is formed of a silicon nitride film, and plays a role of reducing the reflection which originates in a difference of a refractive index between an interlayer insulation film 15 and the semiconductor substrate 11. The multilayer wiring layer 14 is formed of wires which are used for driving such as a readout of the electron generated in the photoelectric conversion portion 12, and a reset, and has an opening provided therein so that light which has been incident from the microlens 17 reaches the photoelectric conversion portion 12. In addition, the multilayer wiring layer 14 of the present embodiment contains a top wiring layer 14a and a middle wiring layer 14b. In between the top wiring layer 14a and the middle wiring layer 14b, the interlayer insulation film 15 is formed which is formed of a silicon oxide film. The color filter 16 is formed from a material which makes light having a particular wavelength band selectively pass therethrough, and has a function of separating the light into colors of R (red), G (green) and B (blue). The microlens 17 plays a role of efficiently collecting light which has been incident on the pixel 10, in the photoelectric conversion portion 12, and has a shape of a convex lens.

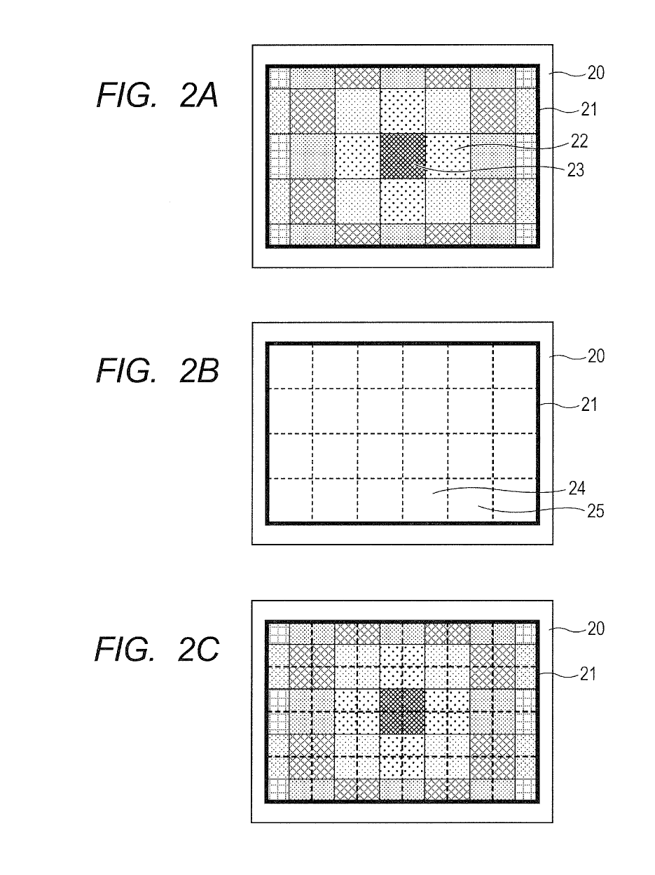

FIGS. 2A to 2C are schematic plan views of the solid-state imaging apparatus 20. The solid-state imaging apparatus 20 has an imaging region 21 on the surface thereof. The imaging region 21 has a plurality of pixels described in FIG. 1 arranged in row and column directions. Each of the pixels 10 on the imaging region 21 outputs a pixel signal. If there are 2,000 pieces of the pixels 10 in the row direction and there are 3,000 pieces of the pixels 10 in the column direction on the imaging region 21 of the present embodiment, the number of pixels is 2,000 pixels in the row direction, 3,000 pixels in the column direction, and 6 millions of pixels in total, and the image region outputs information on the images of the number.

FIGS. 2A and 2B are schematic plan views of the imaging region 21 on the solid-state imaging apparatus 20. FIG. 2A is a plan view illustrating regions of the microlenses 17 in FIG. 1. FIG. 2B is a plan view illustrating regions of the top wiring layer 14a in FIG. 1. FIG. 2C is a view in which the regions of the microlens 17 in FIG. 2A and the regions of the top wiring layer 14a in FIG. 2B are overlapped, and are projected.

As is illustrated in FIG. 2A, the present embodiment has the regions provided in a plurality of rows and columns in the imaging region 21 on an orthographic plane, in which the microlenses 17 in FIG. 1 are arranged. Each of the regions in FIG. 2A has the plurality of microlenses 17 arranged in the row and column directions, and the plurality of microlenses in the region has the same shape.

In the present embodiment, when an arbitrary region illustrated in FIG. 2A is represented by X, the shape of the microlens 17 is different according to each of the regions X. Generally, the shape of the microlens 17 is designed so that the photoelectric conversion portion 12 of the pixel 10 positioned in the center of the region which receives attention can efficiently receive light in a comprehensive way, but is not limited to the above shape in particular. The shape of the microlens 17 is applied to the region that contains the pixels 10 in which the microlenses 17 are arranged respectively, as the common shape of the microlenses 17 in the region.

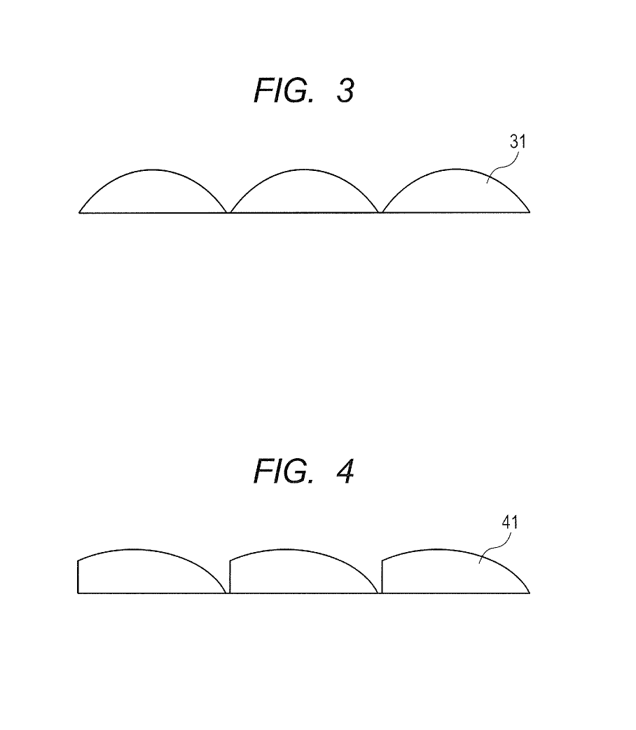

The microlens 17 in a region 23 positioned in the center region of the imaging region 21 in FIG. 2A has a hemispherical shape 31, as is illustrated in FIG. 3. In addition, the microlens 17 in a region 22 positioned in the peripheral region of the imaging region 21 in FIG. 2A has an asymmetric curved surface shape 41, as is illustrated in FIG. 4. In addition, in between the adjacent regions in the imaging region 21 on the orthographic plane, in which the microlenses 17 are arranged, the microlenses arranged in each of the adjacent regions have different shapes from the others. The cross sections of the microlenses illustrated in FIG. 3 and FIG. 4 are cross sections cut in a direction from the center toward the outside of the imaging region 21, in other words, in a direction which passes the top of the microlens. The microlens illustrated in FIG. 3 has a shape which is rotationally symmetric with respect to an axis which passes the top and is perpendicular to the bottom face. The microlens illustrated in FIG. 4 has a (asymmetric) shape which is not rotationally symmetric with respect to the axis passing the top. The top of the microlens 31 in FIG. 3 coincides with the center of gravity of the microlens 31 in an orthographic drawing. The top of the microlens 41 in FIG. 4 does not coincide with the center of gravity of the microlens 41, and is offset from the center of gravity, in the orthographic drawing.

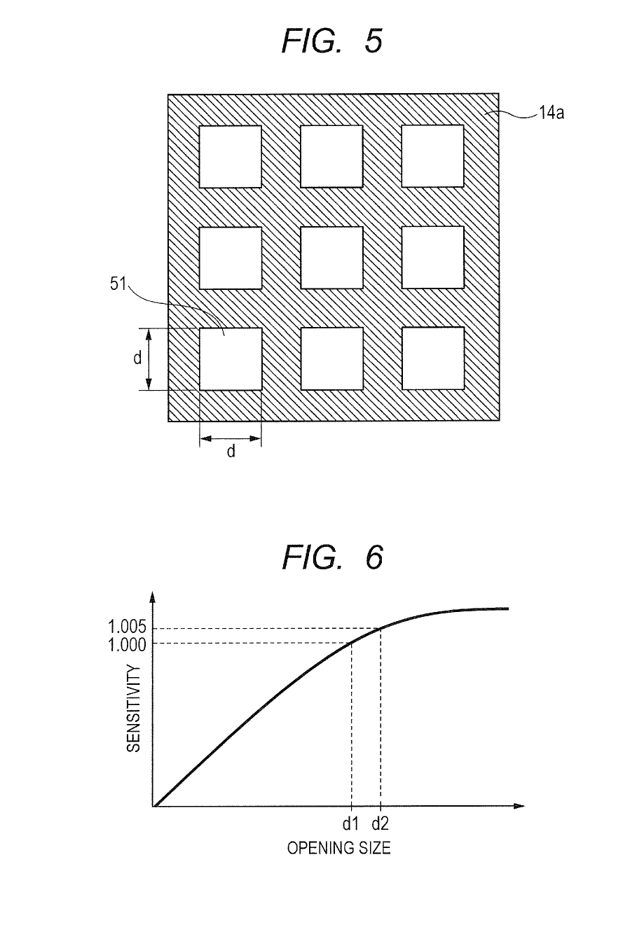

As is illustrated in FIG. 2B, the present embodiment has also regions provided in a plurality of rows and columns in the imaging region 21 on the orthographic plane, in which the top wiring layer 14a in FIG. 1 is arranged. FIG. 5 illustrates a schematic plan view that is a part of FIG. 2B, which is enlarged, and that illustrates the top wiring layer 14a and an opening 51 thereof. Each of the openings 51 is positioned in a light incident side of and perpendicularly above each of the photoelectric conversion portions 12 in FIG. 1. Each of the regions in FIG. 2B has the plurality of openings 51 arranged in the row and column directions, and the plurality of openings in the region has the same size (d×d).

The solid-state imaging apparatus 20 of the present embodiment can be used for an imaging optical system which has a small distance between an imaging lens and the solid-state imaging apparatus, and is particularly used for the region in the imaging region 21, on which a main light beam is incident at a large angle. Here, the case will be considered where a pixel Pᵢ which is positioned in the periphery of a region Xᵢ and a pixel Pᵢ₊₁ which is positioned in the periphery of a region Xᵢ₋₁ are adjacent to each other. The incident angles of the main light beams, which have been used for a design of the microlenses 17 of the pixels Pᵢ and Pᵢ₊₁, imitate the incident angles of the main light beams in the central pixels in the regions to which the pixels 10 belong, respectively. The pixels Pᵢ and Pᵢ₊₁ are adjacent to each other, and accordingly the main light beams which are actually incident on the microlenses 17 approximately coincide with each other. However, the incident angles of the main light beams, which have been used for the design of the microlenses 17, are different from each other, and accordingly a difference occurs between sensitivities at which the photoelectric conversion portions 12 in FIG. 1 detect the light beams, respectively. Then, the sensitivity difference of a rectangular shape that originates in the region in which the microlenses 17 are arranged according to the shape is consequently visually recognized, depending on an image to be imaged.

Here, the optical element means a portion which affects the sensitivity to light incident on the photoelectric conversion portion 12 of the pixel 10 in FIG. 1 and excludes the microlens 17, and includes at least an anti-reflection film 13, a top wiring layer 14a and an opening thereof, a middle wiring layer 14b and an opening thereof, and a color filter 16. In the present embodiment, an example will be described below in which the top wiring layer 14a is adopted as the optical element. In the present embodiment, regions of the microlenses 17 and the optical elements (top wiring layers 14a), which affect the sensitivity of the pixel 10, are overlapped in different positions in the imaging region 21 on the orthographic plane, from each other. Thereby, the discontinuity in sensitivity change can be alleviated, which originates in the region in which the microlenses 17 are arranged according to the shape. For instance, as is illustrated in FIG. 2C, the regions of the microlenses 17 in FIG. 2A and the regions of the top wiring layer 14a in FIG. 2B are arranged in different positions from each other.

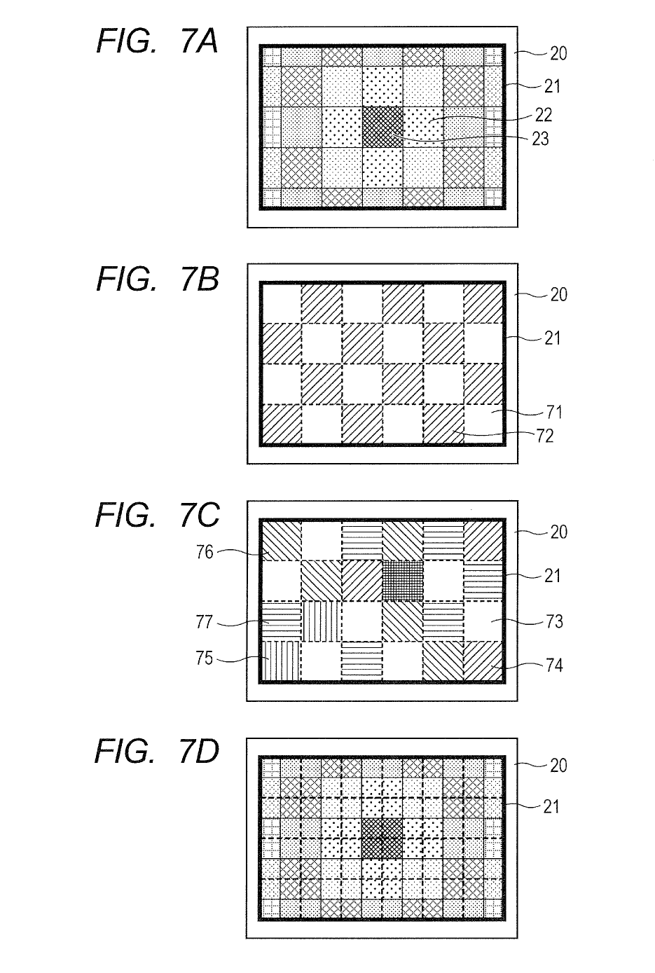

Next, a specific method for arranging the microlenses 17 and the top wiring layer 14a will be described below with reference to FIGS. 2A to 2C, FIG. 5, FIG. 6, and FIGS. 7A to 7D. Firstly, the pixel 10 that is positioned at the center of each of the regions X is determined, with respect to the regions X in the imaging region 21 on the orthographic plane, which is illustrated in FIG. 2A, and in which the microlenses 17 are arranged. Subsequently, such a shape of the microlens 17 is designed that the photoelectric conversion portion 12 of the pixel 10 can most efficiently receive light, when the main light beam is incident on the pixel 10. The shape of the microlens 17 is applied to the region that contains the pixels 10 in which the microlenses 17 are arranged respectively, as the common shape of the microlens 17 in the region. FIG. 7A illustrates the arrangement of the microlenses 17 which have been designed as in the above description, on the orthographic plane of the imaging region 21. Here, it is supposed that the sensitivity difference between the pixel 10 which is positioned at the center in each of the regions and a pixel 10 which is positioned in the same region as the above region and is positioned in the peripheral region, or the sensitivity difference between adjacent pixels 10 which are positioned astride adjacent regions Xᵢ and Xᵢ₊₁, respectively, is in a range of 0 to 1%.

Next, as for a region Y in the imaging region 21 on the orthographic plane, in which the top wiring layer 14a illustrated in FIG. 2B is arranged, the openings 51 in FIG. 5 have the same size in the region Y. As for regions 24 and 25 in FIG. 2B, for instance, a length d of one side of the opening 51 in FIG. 5 is d=d1 in the region 24, and is d=d2 in the region 25. Furthermore, lengths of one side dⱼ and another side dⱼ₊₁+1 of the openings 51 are selected so that an average value of a sensitivity difference between adjacent regions Yⱼ and Yⱼ₊₁ of the top wiring layer 14a does not become larger than an average value of a sensitivity difference between the adjacent regions Xᵢ and Xᵢ₊₁ of the microlens 17. FIG. 6 illustrates a relationship between the size of the opening 51 in the top wiring layer 14a and the sensitivity. The sensitivity monotonically increases along with the enlargement of the opening 51.

FIG. 7B illustrates regions in the imaging region on the orthographic plane, in which such optical elements (top wiring layer 14a) are arranged as to cause two sensitivity differences between the optical elements, and illustrates regions, for instance, of the top wiring layer 14a. In the present embodiment, as in FIG. 7B, a region 71 having the length d1 of one side of the opening 51 and a region 72 having the length d2 of one side of the opening 51 are arranged in a checkered pattern, based on the above described relationship in FIG. 6. Here, the sensitivity difference between the pixels 10 in the adjacent regions 71 and 72 is configured so as to become 0.5%, by the design of d1 and d2.

Incidentally, as for the regions Y in the imaging region 21 having the top wiring layer 14a arranged therein on the orthographic plane, another appropriate method can be adopted as a method for arranging the openings 51 each having the length d of one side, in the regions of the imaging region 21. For instance, such a method is also acceptable as to set the length d of one side of the opening 51 in a range of Expression (1), and add lengths d3, d4 and d5 in the range of d.

d1≦d≦d2 (1)

FIG. 7C illustrates regions in the imaging region on the orthographic plane, in which such optical elements (top wiring layer 14a) are arranged as to cause five sensitivity differences, and illustrates regions, for instance, of the top wiring layer 14a. Regions which have different sizes of the opening 51 from one another may be assigned to the regions of the top wiring layer 14a in the imaging region 21, as in FIG. 7C. For instance, it is acceptable to arbitrarily arrange d1 in a region 73, d2 in a region 74, d3 in a region 75, d4 in a region 76, and d5 in a region 77.

The regions of the microlenses 17, specifically, FIG. 7A, and the regions of the top wiring layer 14a, specifically, FIG. 7B, are overlapped in the same imaging region 21. FIG. 7D is a view in which the arrangement of the regions of the microlenses 17 illustrated in FIG. 7A and the arrangement of the regions of the optical element (top wiring layer 14a) illustrated in FIG. 7B are overlapped. A boundary between the regions according to the shapes of the microlenses 17 is shown by a solid line, and a boundary between the regions according to the sizes of the openings 51 of the top wiring layer 14a is shown by a dotted line.

As for the overlapped drawing of FIG. 7D, each of the regions of the microlenses 17 is equally divided into four by the boundaries between the regions of the top wiring layer 14a. Similarly, each of the regions of the top wiring layer 14a is equally divided into four by the boundaries between the regions of the microlenses 17.

Thus, the region according to the shape of the microlens 17 is divided by the region according to the size of the opening 51 of the top wiring layer 14a. The regions that have different characteristics of the above described optical elements (top wiring layer 14a), which affect the sensitivity of the pixel 10, are overlapped with the regions of the microlenses 17, and thereby smaller regions having different characteristics can be generated. The region in the imaging region 21, which has been generated by the overlap of the region of the microlens 17 and the region of the optical element (top wiring layer 14a), has a surface ratio of 1/4 with respect to the region in the imaging region 21, which has been generated by the shape of the microlens 17.

As has been described above, the microlens 17 and the optical element (top wiring layer 14a) are overlapped in different regions, and thereby the regions having the different sensitivities can be generated with a small region. Accordingly, not only discontinuity in sensitivity characteristics is alleviated, which tends to easily occur in the boundary between the large regions in the imaging region 21 on the orthographic plane, in which the microlenses 17 are arranged, but also an apparent sensitivity difference is alleviated that originates in the sensitivity difference which becomes discontinuous in the unit of the region. Specifically, the sensitivity difference becomes hard to be visually recognized. In addition, the region of the microlenses 17 which are arranged in the imaging region 21 on the orthographic plane does not need to be downsized. Accordingly, the number of the pixels 10 to be designed can be decreased, specifically, a load for designing optical elements of the pixels can be reduced.

Incidentally, in the present embodiment, the regions according to the shape of the microlens 17 and the size of the opening 51 of the top wiring layer 14a in the imaging region 21 on the orthographic plane are set so as to become squares, and the widths of these regions and the distance between the regions are set so as to be equal. However, other forms can be adopted in such a range as not to deviate from the scope. For instance, the region of the microlenses 17 or the optical elements (top wiring layer 14a) may be a polygon, and the shape and the area may be changed for each of the regions. Furthermore, it is desirable to appropriately adjust the region in the imaging region 21 on the orthographic plane according to desired detection conditions of the sensitivity and the space.

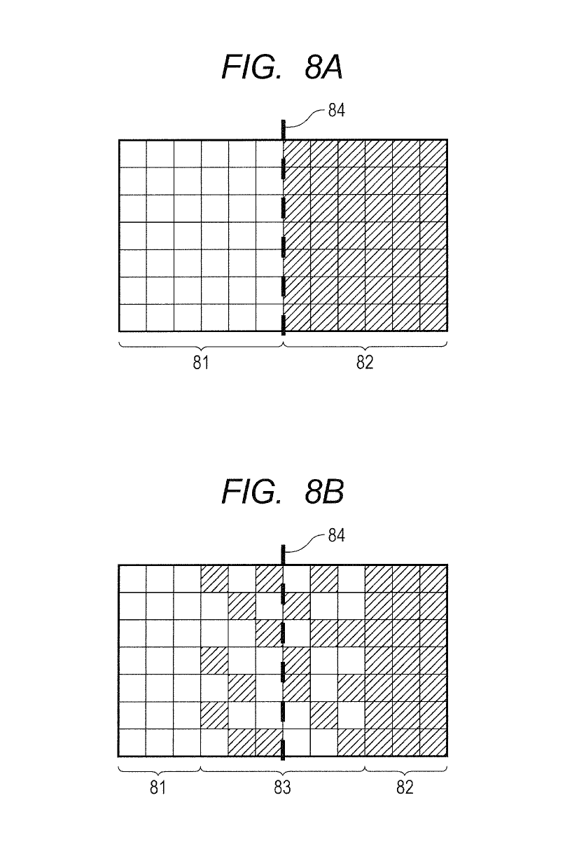

Furthermore, as for the region of the microlenses 17 or the optical elements (top wiring layer 14a), in the boundary portion between the region and the adjacent region, the respective structures may be mixed. The above content will be described below with reference to FIGS. 8A and 8B. The structures usually change from a region 81 to a region 82 astride a boundary 84, as in FIG. 8A. In the case of the top wiring layer 14a of the present embodiment, the length d of one side of the opening 51 changes from d1 to d2 astride the boundary 84. However, here, it is acceptable to provide a mixed region 83 in the boundary portion between the region 81 and the region 82, as is illustrated in FIG. 8B. In this case, the central line of the mixed region 83 becomes the boundary 84 between the regions 81 and 82.

As has been described above, the solid-state imaging apparatus 20 has a plurality of pixels 10 which are arrayed two-dimensionally. Each of the plurality of pixels 10 has the photoelectric conversion portion 12, the optical element (top wiring layer 14a) which is arranged above the photoelectric conversion portion 12, and the microlens 17 which is arranged above the optical element (top wiring layer 14a).

As for the microlenses 17 of the plurality of pixels 10, a plurality of microlenses 17 having the first microlens structure (FIG. 3) are arranged in the first microlens region 23. In addition, a plurality of microlenses 17 having the second microlens structure (FIG. 4) which is different from the first microlens structure are arranged in the second microlens region 22.

The first microlens structure is illustrated by the microlens 31 in FIG. 3. The second microlens structure is illustrated by the microlens 41 in FIG. 4. The first microlens region 23 is a region in a center region among the regions in which the plurality of pixels 10 that are arrayed two-dimensionally. The second microlens region 22 is a region in a peripheral region among the regions in which the plurality of pixels 10 that are arrayed two-dimensionally.

As for the optical elements (top wiring layer 14a) of the plurality of pixels 10, a plurality of optical elements having the first optical element structure are arranged in the first optical element region 71, and a plurality of optical elements having the second optical element structure which is different from the first optical element structure are arranged in the second optical element region 72. The optical element is, for instance, a top wiring layer 14a having the opening 51 therein. The first optical element structure and the second optical element structure are different from each other, in the size of the opening 51.

The first microlens region 23 is positioned above the boundary between the first optical element region 71 and the second optical element region 72, or the boundary between the first microlens region 23 and the second microlens region 22 is positioned above the first optical element region 71.

In addition, in FIG. 8B, a plurality of optical elements having the first optical element structure are arranged in the first optical element region 81, and a plurality of optical elements having the second optical element structure which is different from the first optical element structure are arranged in the second optical element region 82. In the boundary portion 83 between the first optical element region 81 and the second optical element region 82, the optical elements having the first optical element structure and the optical elements having the second optical element structure are mixedly arranged.

In addition, the case will be described below where the first microlens region 23 and the second microlens region 22 are adjacent to each other, and the first optical element region 71 and the second optical element region 72 are adjacent to each other. In the cases, an average value of the sensitivity difference between the optical element of the first optical element region 71 and the optical element of the second optical element region 72 is not larger than an average value of the sensitivity difference between the microlens 31 in the first microlens region 23 and the microlens 41 in the second microlens region 22.

### Second Embodiment

In the solid-state imaging apparatus of a second embodiment of the present invention, the structure of the pixel 10 is the same as that in the first embodiment illustrated in FIG. 1. In addition, the regions according to the shapes of the microlens 17 and in the imaging region 21 on the orthographic plane, in which the microlenses are arranged, are the same as those in the first embodiment illustrated in FIGS. 2A to 2C, FIG. 3 and FIG. 4, and have a sensitivity difference of 0 to 1% between the adjacent regions. In the present embodiment, an example will be described below in which the anti-reflection film 13 is adopted as the optical element.

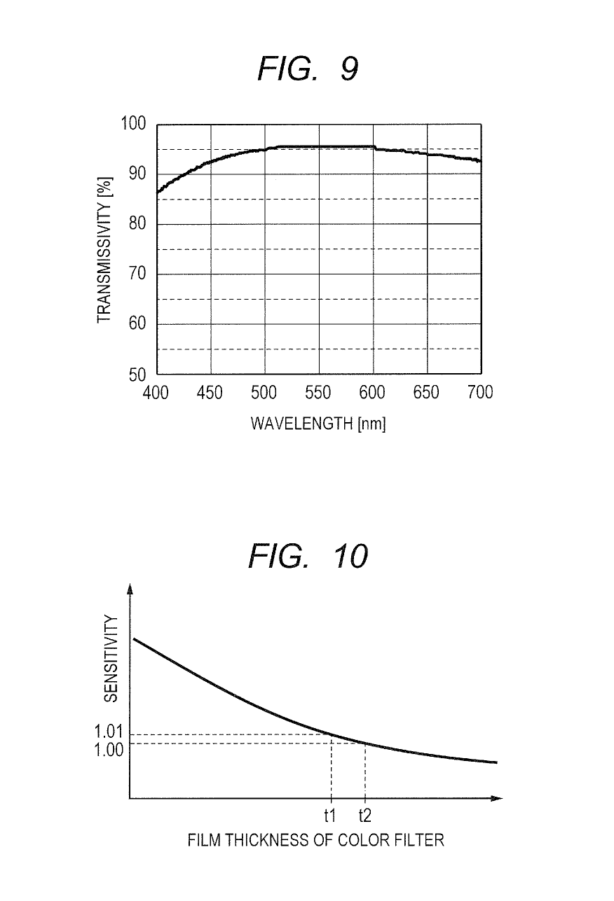

In the second embodiment, the structure of the anti-reflection film (optical element) 13 which is formed on the photoelectric conversion portion 12 and is formed of a silicon nitride film in FIG. 1 is changed for each of the regions. The anti-reflection film 13 is structured, for instance, of an SiO₂ film which is formed on the semiconductor substrate 11 and has a thickness of 10 nm, and an SiN film which is subsequently formed thereon and has a thickness of 50 nm. The wavelength dependency of transmissivity of the thus formed anti-reflection film 13 is illustrated in FIG. 9. The anti-reflection film 13 having the above described structure is designed so that an effect of preventing reflection becomes optimal in a G (green) pixel. When a film thickness of the SiN film decreases, the wavelength at which the transmissivity becomes maximum can be shifted to a B (blue) side, and when the film thickness increases, the wavelength at which the transmissivity becomes maximum can be shifted to an R (red) side. The change of the structure of the anti-reflection film 13 in the present embodiment means that the thickness of the SiN film is changed for each of the regions, and the regions in which the SiN films have two film thicknesses of 50 nm and 60 nm, respectively, are arranged alternately in each of a longitudinal direction and a lateral direction, as in the regions in FIG. 7B. The sensitivities of the SiN films having thicknesses of 50 nm and 60 nm vary by approximately 1%, which can generate the sensitivity difference in the boundary between the regions. In addition, regions in which the SiN films have three or more thicknesses, respectively, may be provided as is illustrated in FIG. 7C.

Thus, the regions in which the shape of the microlens 17 has been changed and the regions in which the film thickness of the anti-reflection film 13 has been changed are formed, and thereby fine regions can be generated by the overlapping in FIG. 7D. Specifically, each of the regions of the microlens 17 is equally divided into four by the boundaries between the regions of the anti-reflection film 13. As a result, the discontinuity in sensitivity change can be alleviated, which originates in the region in the imaging region 21 on the orthographic plane, in which the microlenses 17 are arranged.

As has been described above, in the present embodiment, the optical element is the anti-reflection film 13. As for the optical elements of the plurality of pixels 10, a plurality of optical elements having the first optical element structure are arranged in the first optical element region 71, and a plurality of optical elements having the second optical element structure which is different from the first optical element structure are arranged in the second optical element region 72. The anti-reflection film (optical element) 13 has the SiO₂ film and the SiN film. The first optical element structure and the second optical element structure are different from each other, in the film thickness of the SiN film.

### Third Embodiment

In the solid-state imaging apparatus of a third embodiment of the present invention, the structure of the pixel 10 is the same as that in the first embodiment illustrated in FIG. 1. In addition, the regions according to the shape of the microlens 17 and in the imaging region 21 on the orthographic plane, in which the microlenses 17 are arranged, are the same as those in the first embodiment illustrated in FIGS. 2A to 2C, FIG. 3 and FIG. 4, and have a sensitivity difference of 0 to 1% between the adjacent regions. In the present embodiment, an example will be described below in which the color filter 16 is adopted as the optical element.

In the third embodiment, a film thickness of the color filter 16 is changed for each of the regions illustrated in FIG. 2B, and thereby a difference in sensitivity between adjacent regions is generated. As for the relationship between the film thickness of the color filter 16 and the sensitivity, as the film thickness of the color filter 16 increases, the sensitivity exponentially decreases, as is illustrated in FIG. 10. Because of this, the film thickness of the color filter 16 needs to be selected so that the sensitivity difference originating in the film thickness of the color filter 16 becomes equal to or does not become larger than the sensitivity difference which occurs between the adjacent regions in the imaging region 21 on the orthographic plane, in which the microlenses 17 are arranged. Specifically, the film thickness of the color filter 16 needs to be selected so that a range of the sensitivity difference becomes a range of 1%. For instance, when the relationship between the film thickness of the color filter 16 and the sensitivity as in FIG. 10 is obtained, the film thickness of an arbitrary color filter 16 may be selected within a range between film thicknesses of t1 and t2.

In the present embodiment, the color filters 16 which have two film thicknesses of the film thicknesses t1 and t2, respectively, are arranged alternately in each of the longitudinal direction and the lateral direction, as in FIG. 7B. Here, as well as FIG. 7C, regions may be provided in which the color filters 16 have three or more film thicknesses, respectively. However, patterning such as a photolithography method is needed for individually forming each of the regions, and accordingly the more the number of the film thicknesses of the color filter 16 is, the more the number of processes for the color filter 16 becomes. Because of this, it is more desirable to arrange color filters having two film thicknesses alternately in each of the longitudinal direction and the lateral direction. Thus, the color filters 16 which have two film thicknesses of t1 and t2, respectively, are arranged alternately in each of the longitudinal direction and the lateral direction in the regions in the imaging region 21 on the orthographic plane, and thereby the sensitivity difference of approximately 1% has been generated in the boundary between the adjacent regions.

Thus, the regions according to the shapes of the microlenses 17 and the regions according to the film thicknesses of the color filters 16 are formed, and thereby fine regions can be generated by the overlapping in FIG. 7D. Specifically, each of the regions of the microlenses 17 is equally divided into four by the boundaries between the regions of the color filter 16. As a result, the discontinuity in sensitivity change can be alleviated, which originates in the region in the imaging region 21 on the orthographic plane, in which the microlenses 17 are arranged.

As has been described above, in the present embodiment, the optical element is the color filter 16. As for the optical elements of the plurality of pixels 10, a plurality of optical elements having the first optical element structure are arranged in the first optical element region 71, and a plurality of optical elements having the second optical element structure which is different from the first optical element structure are arranged in the second optical element region 72. The first optical element structure and the second optical element structure are different from each other, in the film thickness of the color filter 16.

### Fourth Embodiment

In the solid-state imaging apparatus of a fourth embodiment of the present invention, the structure of the pixel 10 is the same as that in the first embodiment illustrated in FIG. 1. In addition, the regions according to the shape of the microlens 17 and in the imaging region 21 on the orthographic plane, in which the microlenses 17 are arranged, are the same as those in the first embodiment illustrated in FIGS. 2A to 2C, FIG. 3 and FIG. 4, and have a sensitivity difference of 0 to 1% between the adjacent regions. In the present embodiment, an example will be described below in which the multilayer wiring layer 14 is adopted as the optical element. The multilayer wiring layer 14 has the top wiring layer 14a and the middle wiring layer 14b.

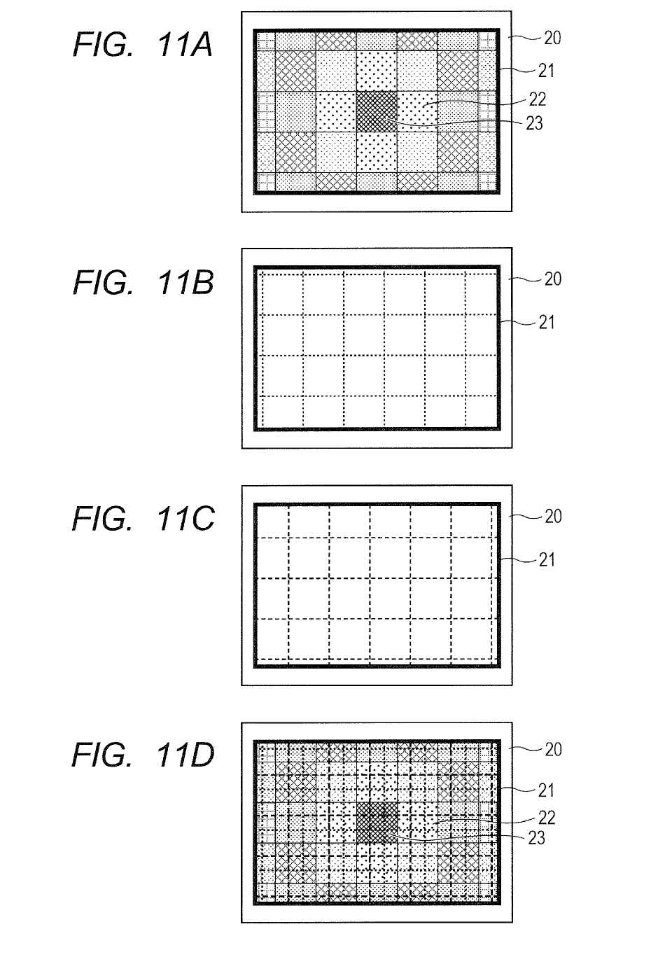

FIGS. 11A to 11D illustrate regions in the imaging region 21 on the orthographic plane, in which the optical elements are arranged, in the solid-state imaging apparatus according to the fourth embodiment. FIG. 11A illustrates regions according to the shapes of the microlenses 17. FIG. 11B illustrates regions according to the sizes of the openings 51 in the top wiring layer 14a. FIG. 11C illustrates regions according to the sizes of the openings in the middle wiring layer 14b. FIG. 11D illustrates regions in which regions in FIGS. 11A to 11C are overlapped.

The regions of the microlenses 17 in FIG. 11A have a sensitivity difference of 0 to 1% between the adjacent regions. The region of the top wiring layer 14a in FIG. 11B is moved in parallel to the region of the microlens 17 in FIG. 11A in an upper left direction, only by a ⅓ region in each of a longitudinal direction and a lateral direction. A length d of one side of the opening 51 in the top wiring layer 14a is set at d1 or d2. Two types of regions of the top wiring layer 14a have openings which have lengths of one side of d1 and d2, respectively, and are arranged in a checkered pattern.

The middle wiring layer 14b in FIG. 11C is positioned one layer below the top wiring layer 14a in FIG. 11B. The region of the middle wiring layer 14b in FIG. 11C is moved in parallel to the region of the microlens 17 in FIG. 11A in a lower right direction, only by a ⅓ region in each of the longitudinal direction and the lateral direction. A value of a length of one side of the opening in the middle wiring layer 14b is selected so that the sensitivity difference becomes approximately 1%, in a similar procedure to that of the time when the lengths d1 and d2 of one side of the opening 51 in the top wiring layer 14a have been determined. In addition, two types of regions of the middle wiring layer 14b are also arranged in a checkered pattern, similarly to those of the top wiring layer 14a.

When the regions of the microlenses 17 in FIG. 11A, the regions of the top wiring layer 14a in FIG. 11B, and the regions of the middle wiring layer 14b in FIG. 11C are overlapped, fine regions are thereby generated each of which corresponds to a size that is obtained by equally dividing the size of the region in which the microlenses 17 are arranged into nine, and consequently, FIG. 11D is obtained. As a result, the discontinuity in sensitivity change can be further alleviated, which originates in the region in the imaging region 21 on the orthographic plane, in which the microlenses 17 are arranged, compared to the first embodiment.

### Fifth Embodiment

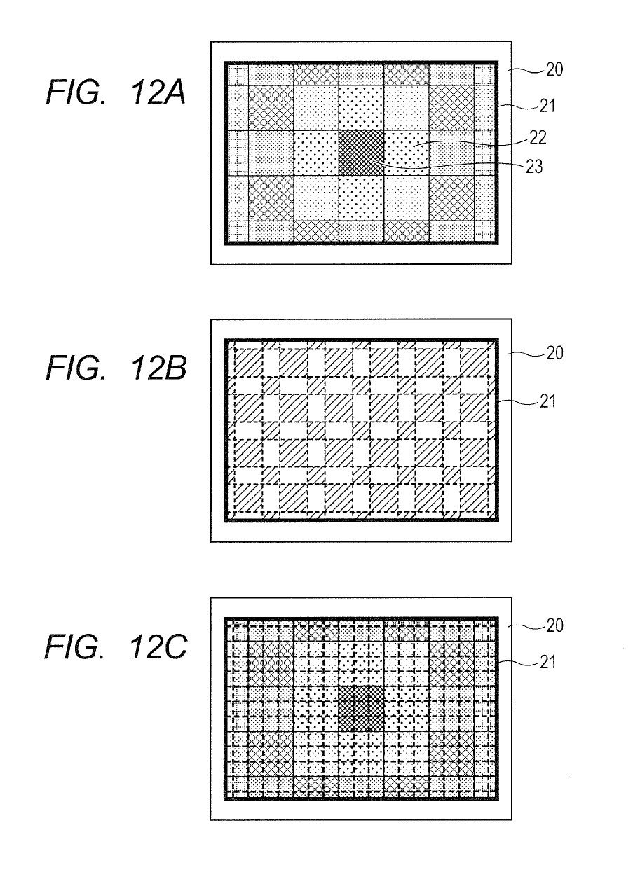

In the solid-state imaging apparatus of a fifth embodiment of the present invention, the structure of the pixel 10 is the same as that in the first embodiment illustrated in FIG. 1. FIGS. 12A to 12C illustrate regions in the imaging region 21 on the orthographic plane, in which the optical elements (top wiring layer 14a) are arranged, in the solid-state imaging apparatus according to the fifth embodiment. FIG. 12A illustrates regions according to the shapes of the microlenses 17. FIG. 12B illustrates regions according to the sizes of the openings in the top wiring layer 14a. FIG. 12C illustrates regions in which regions in FIGS. 12A to 12B are overlapped. In the present embodiment, an example will be described below in which the top wiring layer 14a is adopted as the optical element.

The regions according to shapes of the microlens 17 and in the imaging region 21 on the orthographic plane in FIG. 12A, in which the microlenses 17 are arranged, are similar to those in the first embodiment, and have a sensitivity difference of 0 to 1% between the adjacent regions. The regions of the top wiring layer 14a in FIG. 12B are formed by the overlapping of: the regions which have been moved in parallel to the regions of the microlens 17 in FIG. 12A in an upper left direction, only by a ⅓ region in each of a longitudinal direction and a lateral direction; and the regions which have been moved in parallel to the regions in a lower right direction, similarly only by the ⅓ region. The openings 51 in the top wiring layer 14a, of which one side has a length of d1 or d2, are assigned to the above described regions alternately in a longitudinal direction and a lateral direction.

When the regions of the microlenses 17 in FIG. 12A and the regions of the top wiring layer 14a in FIG. 12B are overlapped in the imaging region 21 on the orthographic plane, FIG. 12C is obtained. In the present embodiment, the region of the top wiring layer 14a in FIG. 12B is formed into a finer region compared to that in the first embodiment, and thereby a fine region can be generated in a region in which characteristics of the microlens 17 and the optical element are overlapped. As a result, the discontinuity in sensitivity change can be alleviated, which originates in the region in the imaging region 21 on the orthographic plane, in which the microlenses 17 are arranged. Thus, the particularly fine region is formed in the optical element which has high flexibility in the design or the production, and thereby the present embodiment can be more simply and effectively carried out.

In addition, the boundary between the regions of the microlenses 17 and the boundary between the regions of the optical elements may be overlapped, but in this case, there is a possibility that a change of the sensitivity in the boundary portion increases. Accordingly, it is desirable to provide the boundary between the regions of the optical elements so as to avoid the boundary between the regions of the microlenses 17, as in the present embodiment.

### Sixth Embodiment

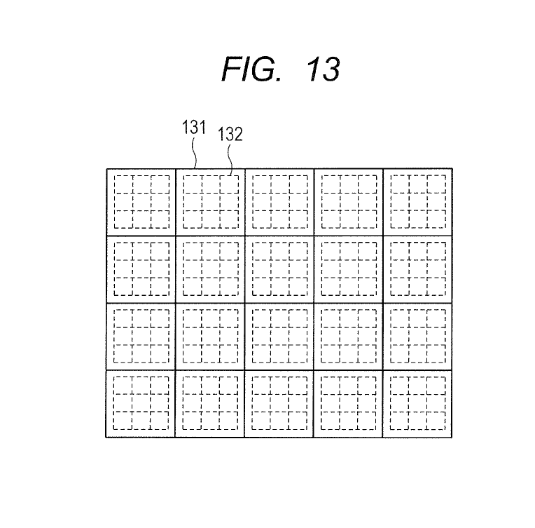

In the solid-state imaging apparatus of a sixth embodiment of the present invention, the structure of the pixel 10 is the same as that in the first embodiment illustrated in FIG. 1. FIG. 13 is a view in which a region 131 according to the shapes of the microlenses 17 and a region 132 according to the sizes of the openings 51 of the top wiring layer 14a are overlapped, according to the sixth embodiment. The regions 131 of the microlens 17 and the regions 132 of the top wiring layer 14a are different from each other in the size. For instance, each of the regions 131 of the microlens 17 is subdivided (here, equally divided into nine) by the regions 132 of the top wiring layer 14a. As a result, the discontinuity in sensitivity change can be alleviated, which originates in the region in the imaging region 21 on the orthographic plane, in which the microlenses 17 are arranged.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

The present invention is not limited to the above described embodiments, and can be appropriately changed and modified in such a range as not to deviate from the object and scope of the present invention. In addition, the above described embodiments can be applied to an imaging system which is represented by a camera or the like. A concept of the imaging system includes not only an apparatus mainly for the purpose of photographing but also an apparatus which is auxiliarily provided with a photographing function (for instance, personal computer and mobile terminal). The imaging system includes the solid-state imaging apparatus exemplified in any one of the above described embodiments, and a signal processing portion which processes a signal output from the solid-state imaging apparatus. The signal processing portion includes, for instance, an A/D converter and a processor which processes digital data output from the A/D converter.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-231765, filed Nov. 14, 2014, which is hereby incorporated by reference herein in its entirety.

What is claimed is:

1. A solid-state imaging apparatus comprising:
a plurality of pixels arranged two-dimensionally, wherein
each of the plurality of pixels has
a photoelectric conversion portion,
an optical element arranged above the photoelectric conversion portion, and
a microlens arranged above the optical element, wherein
the microlenses of the plurality of pixels include a plurality of microlenses of a first microlens structure arranged in a first microlens region, and a plurality of microlenses of a second microlens structure different from the first microlens structure arranged in a second microlens region,
the optical elements of the plurality of pixels include a plurality of optical elements of a first optical element structure arranged in a first optical element region, and a plurality of microlenses of a second optical element structure arranged in a second optical element region, and
the first microlens region is arranged above a boundary between the first and second optical element regions.

2. The solid-state imaging apparatus according to claim 1, wherein
the optical element is a wiring layer having an opening.

3. The solid-state imaging apparatus according to claim 2, wherein
sizes of the openings of the first and second optical elements are different form each other.

4. The solid-state imaging apparatus according to claim 1, wherein
the optical element is an anti-reflection film having an opening.

5. The solid-state imaging apparatus according to claim 4, wherein
the anti-reflection film includes SiO₂ film and a SiN film.

6. The solid-state imaging apparatus according to claim 1, wherein
the optical element is a color filter.

7. The solid-state imaging apparatus according to claim 6, wherein
film thicknesses of the color filters of the first and second optical element structures are different from each other.

8. The solid-state imaging apparatus according to claim 1, wherein
the first microlens structure is a microlens of a shape of a rotational symmetry with respect to an axis passing through a top thereof, and
the second microlens structure is a microlens of a shape of a non-rotational symmetry with respect to an axis passing through a top thereof.

9. The solid-state imaging apparatus according to claim 8, wherein
the first microlens region is a center region in the plurality of pixels arranged two-dimensionally, and
the second microlens region is a peripheral region in the plurality of pixels arranged two-dimensionally.

10. The solid-state imaging apparatus according to claim 1, wherein
the optical elements of the first and second optical element structures are arranged mixedly at a boundary between the first and second optical element regions.

11. The solid-state imaging apparatus according to claim 1, wherein
the first and second microlens regions are adjacent to each other,
the first and second optical element regions are adjacent to each other,
an average value of a sensitivity difference between the optical elements in the first optical element region and the optical elements in the second optical element region is smaller than a sensitivity difference between the microlenses in the first microlens region and the microlenses in the second microlens region.
